(19) United States
(12) Patent Application Publication
(10) Pub. No.: US 2006/0145136 A1
(43) Pub. Date: Jul. 6, 2006

(54) Quantum dot memory

(76) Inventor: Martin Verhoeven, Radebeul (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/025,852

(22) Filed: Dec. 30, 2004

(51) Int. Cl. H01L 31/109

(52) U.S. Cl. 257/14

(57) ABSTRACT

Provided is a method for fabricating self-assembled regions of silicon as well as semiconductor memory cells based thereon. By structuring a layer of silicon prior to thermal formation of the self-assembled regions under vacuum conditions control of location of these regions is achieved. A chargeable self-assembled region of silicon acts as a floating gate of a quantum dot DRAM including a control gate, a channel region within a semiconductor substrate and source and drain regions formed therein.

### FIELD OF THE INVENTION

This invention relates generally to a method for fabricating self-assembled regions of silicon as well as semiconductor memory cells based thereon and more particularly, to a quantum dot dynamic random access memory (DRAM).

### BACKGROUND OF THE INVENTION

Present dynamic random access memories (DRAMs) use trench or stack capacitors to store charge. For readout, charge sharing with the bit line is utilized. Although lithographic dimensions have shrunk, while the operation temperature and therefore the thermal noise is kept constant, capacitance values have not dropped much below 25 fF. Additionally, as storage voltages tend to drop in order to limit power consumption, the available store charge is further reduced. Thus, further lateral shrinking of memory cells requires new memory cell concepts as present memory cell concepts become harder and harder to realize.

The use of self-assembled regions of silicon, e.g., quantum dots formed as hemispherical silicon grains, to store charge, e.g., on a floating quantum dot, allows further shrinkage of DRAM cells for nodes beyond 50 nm.

However, providing a DRAM consisting of memory cells based on quantum dots requires control of size and especially of location of these quantum dots, which are also referred to as nano-dots.

In a publication by A. Sakai et al., entitled “Novel seeding method for the growth of polycrystalline silicon films with hemispherical grains,” Applied Physics Letters 61 (2), 13 Jul. 1992, pp 159-161, a novel method for the fabrication of hemispherical grained polycrystalline silicon films, which is applicable to high capacitance storage electrodes for dynamic random access memory cells, has been developed. This technique consists of first seeding an amorphous silicon surface with crystalline silicon nuclei at an elevated substrate temperature using silicon molecular-beam deposition. Upon subsequent isothermal annealing under ultrahigh vacuum conditions, it was found, that silicon microcrystals act as nuclei for the formation of hemispherical silicon grains. Although hemispherical silicon grains can be formed with uniform grain size, their distribution on the amorphous silicon layer is inhomogeneous (see FIG. 3 of this publication).

Spontaneously fabricated nanometer-scale silicon quantum dots on SiO₂ by controlling the early stages of low-pressure chemical vapor deposition from pure silane are described in the publication entitled “Resonant tunneling through a self-assembled silicon quantum dot,” Applied Physics Letters 70 (17), 28 Apr. 1997. Dot heights varied from 1.5 nm to 8 nm with a dot diameter in the range of 10 nm-20 nm. The distribution of quantum dots on the SiO₂ layer is inhomogeneous (see FIGS. 1a and 1b of this publication).

In the publication by P. W. Lee et al., entitled “Fabrication of a germanium quantum-dot single-electron transistor with large Coulomb-blockade oscillations at room temperature,” Applied Physics Letters, Volume 85, No. 9, 30 Aug. 2004, a simple and complementary metal-oxide-semiconductor-compatible method for fabricating germanium single-electron transistors is proposed, in which the germanium quantum dots are naturally formed by selective oxidation of Si_{0.95}Ge_{0.05}/Si wires on a silicon-on-insulator substrate. The distribution of the germanium nanocrystals embedded between a growing oxide and a buried oxide layer is inhomogeneous (see FIG. 2B).

### SUMMARY OF THE INVENTION

The present invention provides a method for fabricating self-assembled regions of silicon comprising the steps of providing a semiconductor substrate, forming an insulating layer on the semiconductor substrate, forming a layer of silicon on top of the insulating layer, lithographically structuring the layer of silicon in order to define regions of silicon at predetermined positions on the insulating layer and thermally annealing the regions of silicon under vacuum conditions in order to form self-assembled regions of silicon. Lithographically structuring the silicon layer allows control of the positions of the self-assembled regions, so that an array-like assembly for the realization of a memory comprising a plurality of memory cells may be provided. The layer of silicon may be amorphous or comprise any degree of crystallinity, e.g., being nano-crystalline, poly-crystalline, multi-crystalline or mono-crystalline.

It is preferable that the annealing temperature lies within a temperature range of about 450° C. to about 800° C. taking into account that, depending on the lithographically defined dimensions of the regions of silicon, silicon particles require a minimum, temperature-dependent diffusion length to reach hemispherical silicon grain formation. Hemispherical silicon grain formation for lithographic dimensions of the regions of silicon lying in a range of 100 nm conveniently requires annealing temperatures of about 850° C., whereas for lithographic dimensions of about 50 nm an annealing temperature of about 700° C. is appropriate for hemispherical silicon grain formation.

The semiconductor substrate may be formed of one of the group consisting of silicon, germanium and a combination thereof. Use of a silicon substrate is advantageous, since it permits incorporation of the formation of the self-assembled regions of silicon into silicon process technology.

The insulating layer on the semiconductor substrate may be formed of one of the group of silicon oxide, aluminum oxide, tantalum oxide, titanium oxide, titanates and tantalates of zircon, bismuth, strontium, hafnium, barium and a combination thereof. When using the self-assembled regions of silicon as a floating gate of a memory cell, the insulating layer will act as a barrier layer when charging/discharging the floating gate. Thus, a retention time and a write time of the memory cell depend on the barrier the insulating layer forms at the interfaces to the floating gate and the semiconductor substrate, thereby determining characteristics of charging and discharging the floating gate.

It is preferable that the silicon layer is lithographically structured into an assembly of regions of silicon arranged in columns and rows, wherein the regions of silicon are separated from each other. Thus, an assembly of aligned memory cells based on lithographically structured self-assembled regions of silicon may be formed.

To provide a method for fabricating an assembly of memory cells, the method for fabricating self-assembled regions of silicon is extended to further include the steps of forming a top insulating layer over the self-assembled regions of silicon to provide self-assembled regions of floating silicon, forming buried bitlines within the semiconductor substrate lying essentially between neighboring columns of the self-assembled regions of silicon to provide source and drain regions to the memory cells and forming wordlines to define control gates of the memory cells lying essentially perpendicular to the columns along rows on the self-assembled regions of silicon by providing a conductive layer on the top insulating layer and structuring the conductive layer by etch-back. The conductive layer may be formed as a doped layer of polycrystalline silicon or as a metal layer. Self-assembled regions of floating silicon may be utilized in a memory cell to store charge and thereby alter the threshold voltage of the memory cell. Advantageously, the top insulating layer is provided with a larger thickness compared to a thickness of the insulating layer lying between the semiconductor substrate and the self-assembled regions of floating silicon. The buried bitlines providing source and drain regions to the memory cells may be formed by ion implantation. The buried bitlines and the wordlines do not necessarily have to be formed as straight lines, but can also be formed in terms of a meander essentially extending along a direction of the columns and rows. Likewise, alternative designs of the bitlines and the wordlines are feasible when realizing various layout concepts of DRAM memory cells and their assembly. The thickness of the insulating layer should be chosen thin enough to allow for a rapid charging of the self-assembled regions of floating silicon, but it should also be thick enough to provide a retention time which is comparable or even better compared to retention times of present DRAMs.

The silicon layer may also be lithographically structured into an assembly of regions of silicon arranged in stripes that are separated from each other. These regions of silicon may be used as nano-wires to conduct current or store charge, for instance.

According to the present invention, there is provided a memory cell comprising: a semiconductor substrate, an insulating layer on the semiconductor substrate, one quantum dot on the insulating layer having a thickness essentially decreasing from an inner part to an outer part of the quantum dot, a top insulating layer covering the quantum dot to provide a floating quantum dot, buried bitlines within the semiconductor substrate below the insulating layer to provide source and drain of the memory cell arranged laterally adjacent to the quantum dot, and a wordline on at least a part of the top insulating layer to provide a control gate for operating the memory cell. The one quantum dot is preferably formed as a self-assembled, self-contained region of silicon. The insulating layer on the semiconductor substrate is used as a tunnel oxide being thin enough to allow for rapid charging of the quantum dot but also allowing for a retention time comparable or even better compared to present DRAMs. Readout of such a memory cell is performed by sensing the current flow along a channel between source and drain for a given voltage supplied on the control gate. As charge stored within the quantum dot screens charge of the control gate with respect to a channel region, a channel current can thus be controlled. In other words, charge stored within the quantum dot shifts the threshold voltage of the memory cell.

It should be noted that a memory cell concept that is different from the buried bitline concept, e.g., a shallow trench isolated cell concept, may also be used to realize a memory cell based on the self-assembled region of silicon.

It is preferable that the quantum dot is a hemispherical silicon grain. Lateral dimensions of the hemispherical silicon grain lie preferably within a range of about 5 nm to about 50 nm in order to enable realization of semiconductor devices having dimensions below 50 nm.

It is preferable that the thickness of the insulating layer lies within a range of about 0.5 nm to about 2 nm to provide a sufficient charging speed of the quantum dot compatible with prospected DRAM speeds of upcoming memory generations using SiO₂ as a material of the insulating layer.

The control gate may be made by one of the group consisting of doped polycrystalline silicon and metal. However, further materials may be used when fulfilling requirements regarding process integration and specific resistance.

The present invention aims to provide an assembly of memory cells arranged in rows and columns with buried bitlines essentially formed along the columns and wordlines essentially formed along the rows, wherein a bitline of neighboring memory cells arranged along a word line is common to the neighboring cells. Thus, a space saving cell concept of a 4F2 with a quantum dot DRAM structure can be achieved.

It should be noted that features of any of the claims may be combined to define an embodiment within the scope of the present invention.

### BRIEF DESCRIPTION OF THE DRAWING

The above objects and advantages of the present invention will become more apparent by describing in detail preferred embodiments thereof with reference to the drawings in which:

FIGS. 1-3B are cross-sectional views showing different steps during formation of self-assembled regions of silicon according to an embodiment of the present invention.

FIGS. 4-6 are cross-sectional views showing different steps during formation of an assembly of memory cells according to an embodiment of the present invention.

FIG. 7 is a lithographic mask for structuring a layer of silicon to define structures as shown in FIGS. 2A and 2B.

FIG. 8 is a lithographic mask to define buried bitlines as shown in FIG. 5.

FIG. 9 is a lithographic mask to define wordlines as shown in FIG. 6.

FIG. 10 is a schematic top view on a quantum dot DRAM memory comprising memory cells arranged in rows and columns according to an embodiment of the present invention.

FIG. 11 shows regions of silicon that are lithographically structured into stripes according to an embodiment of the present invention.

FIG. 12 shows nano-wires of silicon.

### DESCRIPTION OF THE PREFERRED EMBODIMENTS

The present invention will now be described with reference to the accompanying drawings.

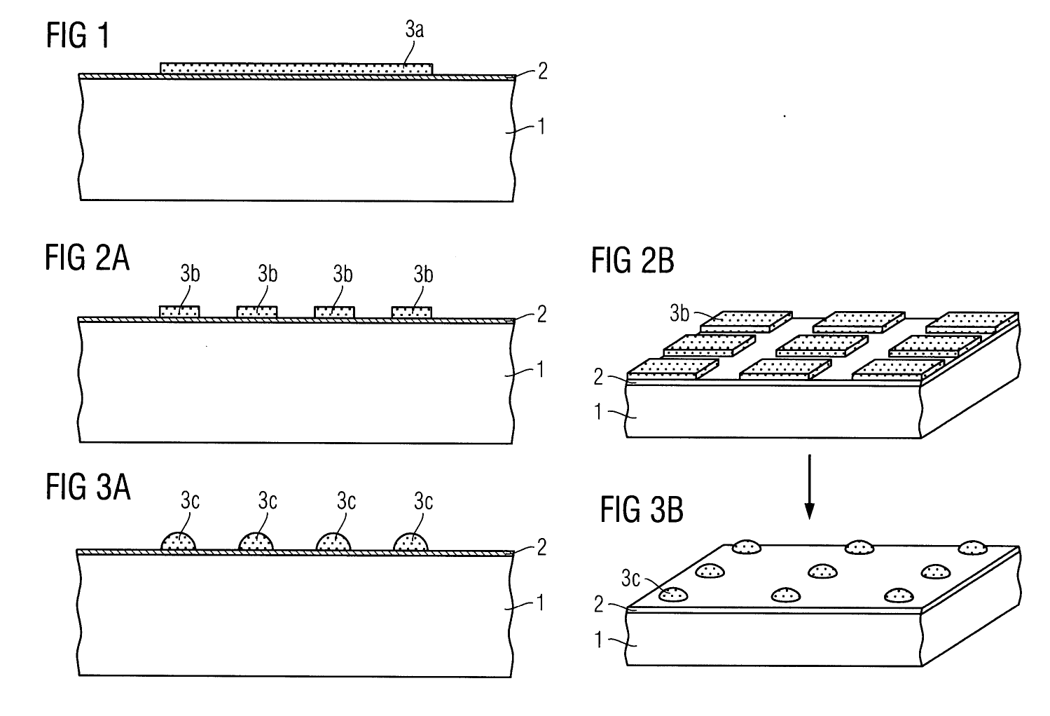

Referring now to the drawings, FIG. 1 shows a cross-sectional view of a semiconductor substrate 1, on top of which an insulating layer 2, preferably a SiO₂ layer, is formed. A layer of silicon 3a, either amorphous or of any crystallinity, is additionally formed on top of the insulating layer 2. The structure as shown in FIG. 1 serves as a starting point for the formation of self-assembled regions of silicon. It should be noted that the insulating layer 2 is ultra-thin having a thickness of preferably about 0.5 nm to about 2 nm.

FIG. 2A shows a sectional side view of the structure of FIG. 1 after lithographically structuring the layer of silicon 3a. FIG. 2B is a top perspective view of the structure of FIG. 1 after lithographically structuring the layer of silicon 3a into regions of silicon 3b that are separated from each other. By structuring the layer of silicon 3a prior to an annealing step under vacuum conditions, the location of self-assembled regions of silicon that may be formed in subsequent steps can be controlled. A thickness of the layer of silicon 3a will define a size of self-assembled regions of silicon, e.g., hemispherical silicon grains, as it acts as a material reservoir when forming these regions.

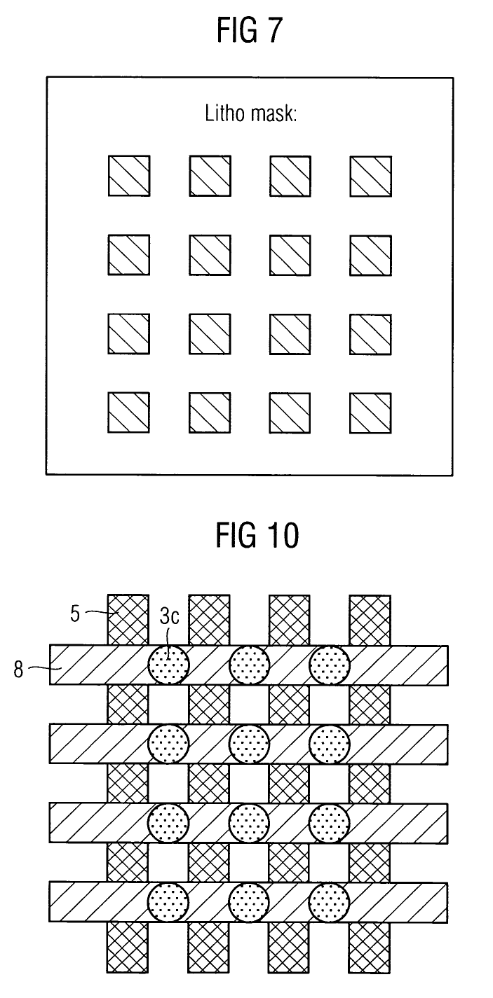

FIG. 7 shows a lithographic mask to define the regions of silicon 3b as shown in FIGS. 2A and 2B.

FIGS. 3A and 3B respectively illustrate a side view and a top perspective view of the structure of FIGS. 2A and 2B after thermally annealing the regions of silicon 3b under vacuum conditions. When thermally annealing the regions of silicon 3b, preferably at temperatures of about 450° C. to about 800° C., the regions 3b reorganize to form self-assembled regions of silicon 3c in terms of horizontal silicon grains. This formation can be ascribed to the fact that silicon, when annealed under vacuum conditions, self-organizes into horizontal silicon grains with a very narrow grain size distribution. It should be noted, that horizontal silicon grains help to increase an effective surface area of present deep trench capacitors.

The present invention has been described with reference to a preferred embodiment of a fabrication method for self-assembled regions silicon 3c, e.g. nano-dots 3c. A structure providing these nano-dots 3c may be further processed to form a quantum dot DRAM.

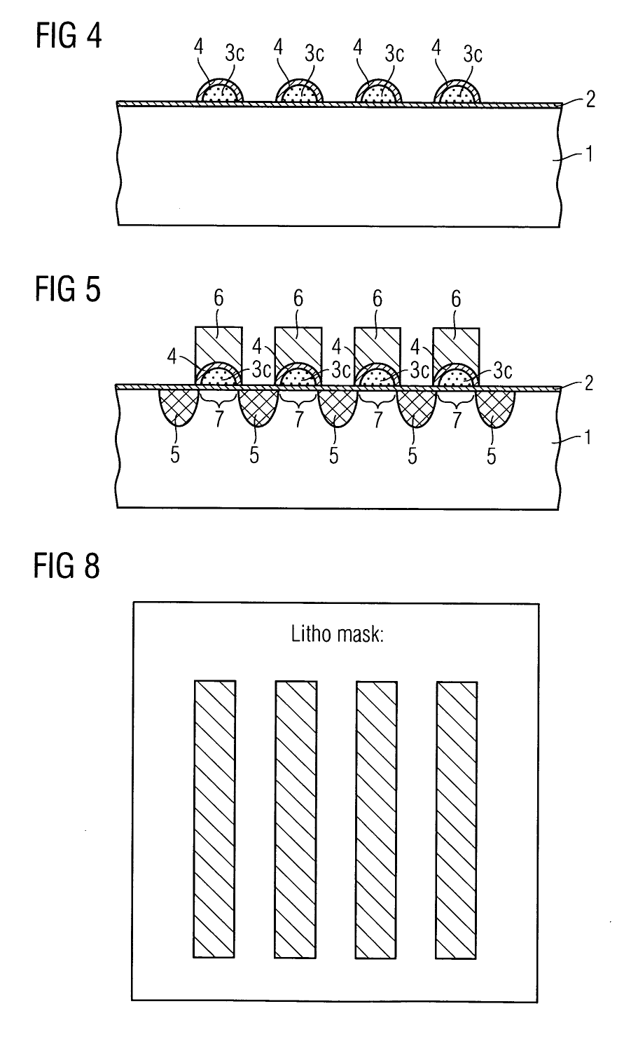

FIG. 4 shows the structure of FIG. 3A after formation of a top insulating layer 4 on the self-assembled regions of silicon 3c according to an embodiment of the present invention. It should be noted that the quantum dots 3c are floating quantum dots isolated by the insulating layer 2 and the top insulating layer 4. The top insulating layer 4 preferably comprises a thickness larger than a thickness of the insulating layer 2. The thickness of the top insulating layer 4 may be adjusted by either an appropriate single formation step, e.g., deposition, or by separate steps, e.g., deposition followed by thickening of the deposited layer. It is preferable that the top insulating layer 4 have a thickness of at least about 2 nm or about 2 times greater than the thickness of the insulating layer 2.

FIG. 5 shows the structure of FIG. 4 after formation of buried bitlines 5, e.g., by ion implantation using a lithographically structured mask 6. It should be noted that the buried bitlines 5 are formed below the insulating layer 2, wherein each bitline is common to neighboring memory cells, each memory cell comprising one quantum dot 3. Regions within the semiconductor substrate 1 located below the insulating layer 2 in between neighboring buried bitlines 5 define channel regions 7 of the memory cells.

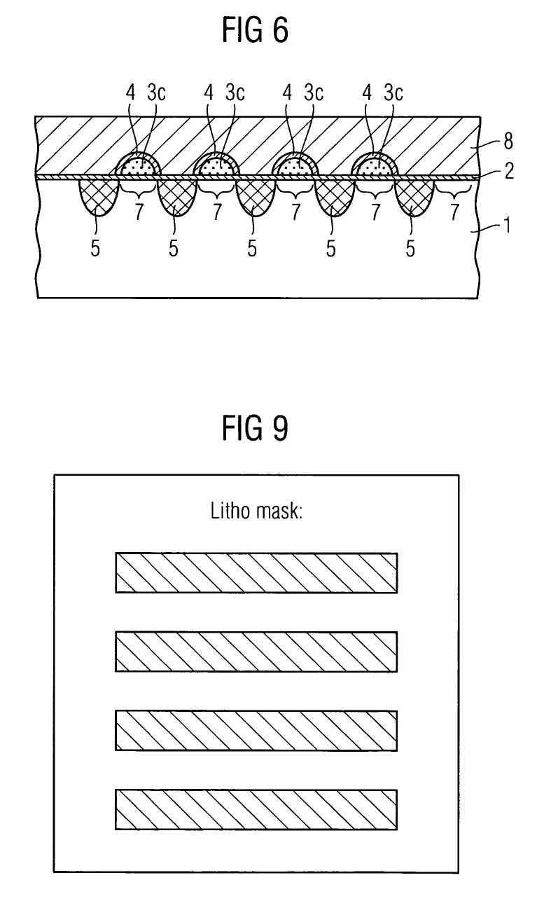

FIG. 6 shows the structure of FIG. 5 after removal of the mask 6 and formation of a wordline 8 acting as a control gate 8 to operate the memory cells. The wordline 8 lies essentially perpendicular to the buried bitlines 5.

When forming the buried bitlines 5 and wordlines 8, lithography using masks as shown in FIG. 8 respective the formation of the buried bitlines 5 and in FIG. 9 respective the formation of the wordlines 8 may be used.

FIG. 10 shows a top view of a quantum dot DRAM memory comprising an assembly of memory cells arranged in rows and columns according to an embodiment of the present invention. The wordline 8 is formed over the quantum dots 3c that are essentially lying in between neighboring buried bitlines 5. The memory concept as shown in FIG. 10 provides an area saving 4F2 cell design.

Referring now to FIGS. 10 and 6 an example of an estimation of a write time for a quantum dot DRAM memory cell with typical dimensions of a diameter of 40 nm, a thickness of the insulating layer 2 of 1 nm and a thickness of the top insulating layer 4 of 2 nm will be given. Both insulating layers 2, 4 are considered as oxide layers, whereas the conductivity of the insulating layer 2 at an electric field strength of 10⁷ V/m is taken as 10⁴ A/cm² leading to a tunnel barrier resistivity of several kΩcm. The overall capacitance of the quantum dot 3c is about 10-16 F leading to a RC-time constant of about 0.8 ns, compatible with prospected DRAM speeds. The overall stored charge within the quantum dot 3c will amount to about several 1000 electrons sufficiently localized to show single electron tunneling effects due to a high barrier resistance (8 Mω>>h/4e²). A retention time of the memory cell will be longer than a write time due to the small number of electrons escaping in a statistical tunneling process out of the quantum dot 3c that is acting as a floating gate. The escape rate is likely dominated by thermal activation with a decay time t_{d} given by t_{d}=t₀ exp(E_{b}/kT), t₀ being in the order of 10⁻¹³ s, a barrier energy of E_{b} of 3.5 eV, k being the Boltzmann's constant and T specifying room temperature.

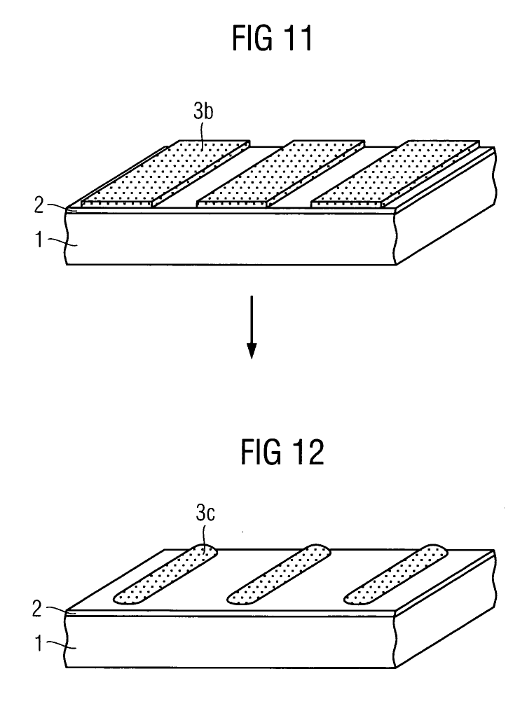

FIG. 11 shows a perspective view on regions 3b of silicon arranged in stripes separated from each other and insulated from the semiconductor substrate 1 by the insulating layer 2.

FIG. 12 shows a view of the structure of FIG. 11 after thermally annealing the structure under vacuum conditions to grow self-assembled regions 3c of silicon in terms of nano-wires 3c. The position of the nano-wires 3c is defined by lithography when structuring the regions 3b of silicon as shown in FIG. 11. The dimensions of the nano-wires 3c are given by an initial thickness of the regions 3b of silicon. The nano-wires 3c as described above are suited to conduct current or store charge, for instance. Therefore the nano-wires 3c as well as the nano-dots 3c may be appropriately doped when forming the layer of silicon 3a at the beginning of the fabrication process.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCE SIGNS

1 semiconductor substrate
2 insulating layer
3a layer of silicon
3b region of silicon
3c self-assembled region of silicon, quantum dot, nano-dot, nano-wire
4 top insulating layer
5 buried bitline
6 mask
7 channel region
8 wordline

What is claimed is:

1. A method for fabricating self-assembled regions of silicon, comprising:
providing a semiconductor substrate;
forming an insulating layer on the semiconductor substrate;
forming a layer of silicon on top of the insulating layer;
lithographically structuring the silicon layer in order to define regions of silicon at predetermined positions on the insulating layer; and
thermally annealing the regions of silicon under vacuum conditions in order to form self-assembled regions of silicon.

2. The method of claim 1, wherein the temperature when thermally annealing the regions of silicon lies within a range of about 450° C. to about 800° C.

3. The method of claim 1, wherein the semiconductor substrate comprises one of the group consisting of silicon, germanium and a combination thereof.

4. The method of claim 1, wherein the insulating layer comprises one of the group of silicon oxide, aluminum oxide, tantalum oxide, titanium oxide, titanates and tantalates of zircon, bismuth, strontium, hafnium, barium and a combination thereof.

5. The method of claim 1, wherein the layer of silicon is lithographically structured into an assembly of the regions of silicon arranged in columns and rows so that the regions of silicon are separated from each other.

6. The method of claim 5 for fabricating an assembly of memory cells, further comprising:
forming a top insulating layer on the self-assembled regions of silicon to provide self-assembled regions of floating silicon;
forming buried bitlines within the semiconductor substrate lying essentially between neighboring columns of the self-assembled regions of silicon to provide source and drain regions of the memory cells; and
forming wordlines to define control gates of the memory cells lying essentially along rows on the self-assembled regions by providing a conductive layer on the top insulating layer and structuring the conductive layer by etch-back.

7. The method of claim 1, wherein the layer of silicon is lithographically structured into an assembly of regions of silicon arranged in stripes that are separated from each other.

8. A memory cell, comprising:
a semiconductor substrate;
an insulating layer on the semiconductor substrate;
a quantum dot on the insulating layer having a thickness essentially decreasing from an inner part to an outer part of the quantum dot;
a top insulating layer covering the quantum dot on the insulating layer to provide a floating quantum dot;
buried bitlines within the semiconductor substrate below the insulating layer to provide source and drain regions of the memory cell that are laterally adjacent to the quantum dot; and
a wordline on at least a part of the top insulating layer to provide a control gate for operating the memory cell.

9. The memory cell of claim 8, wherein the quantum dot is a hemispherical silicon grain.

10. The memory cell of claim 9, wherein the hemispherical silicon grain has lateral dimensions within a range of about 5 nm to about 50 nm.

11. The memory cell of claim 8, wherein the semiconductor substrate comprises one of the group consisting of silicon, germanium and a combination thereof.

12. The memory cell of claim 8, wherein the thickness of the insulating layer lies within a range of about 0.5 nm to about 2 nm.

13. The memory cell of claim 8, wherein the material of the insulating layer comprises one of the group consisting of silicon oxide, aluminum oxide, tantalum oxide, titanium oxide, titanates and tantalates of zircon, bismuth, strontium, hafnium, barium and a combination thereof.

14. The memory cell of claim 8, wherein the wordline comprises one of the group consisting of poly-crystalline silicon and metal.

15. An assembly of memory cells, wherein the memory cells are formed according to claim 8;
the memory cells are arranged in rows and columns, the buried bitlines are essentially formed along the columns, and the wordlines are essentially formed along the rows; and
a bitline of neighboring memory cells that are arranged along a wordline is common to the neighboring memory cells.
